(19) United States
(12) Patent Application Publication
(10) Pub. No.: US 2026/0247577 A1
(43) Pub. Date: Aug. 20, 2026

(54) BASE STATION DEVICE AND METHOD OF COOLING BASE STATION DEVICE

(71) Applicant: NEC Corporation, Tokyo (JP)

(72) Inventors: Mahiro HACHIYA, Tokyo (JP); Yasuhiro Kubota, Tokyo (JP); Taro Hirose, Tokyo (JP)

(73) Assignee: NEC Corporation, Tokyo (JP)

(21) Appl. No.: 19/421,202

(22) Filed: Dec. 16, 2025

(30) Foreign Application Priority Data
Dec. 19, 2024 (JP) 2024-223975

(51) Int. Cl. H05K 7/20; H01Q 1/02

(52) U.S. Cl. CPC H05K 7/20418; H01Q 1/02

(57) ABSTRACT

Provided is a base station device and the like capable of improving heat dissipation performance by using a heat sink including a base and a heat dissipation fin provided obliquely with respect to the base in a naturally air-cooled base station device. There is provided a base station device including a device body installed at a depression angle, and a heat sink attached to the device body, in which the heat sink includes a base including a base surface and at least one heat dissipation fin, and the heat dissipation fin is provided obliquely with respect to the base surface.

### INCORPORATION BY REFERENCE

This application is based upon and claims the benefit of priority from Japanese patent application No. 2024-223975, filed on Dec. 19, 2024, the disclosure of which is incorporated herein in its entirety by reference.

### TECHNICAL FIELD

The present disclosure relates to a base station device and a method of cooling the base station device.

### BACKGROUND ART

FIG. 13 is a perspective view of a heat sink 200 described in WO 2021/148140 A1. FIG. 14 is a perspective view of a heat sink 300 described in WO 2023/246095 A1. In FIGS. 13 and 14, the X-axis represents the device lateral direction. The Y-axis represents the device longitudinal direction. The Z-axis represents the device thickness direction.

Conventionally, for example, as illustrated in FIG. 13, the heat sink 200 including a base 201 and a heat dissipation fin 202 is known in WO 2021/148140 A1. The heat dissipation fins 202 on both sides in the X direction are provided obliquely with respect to the Y axis in a base surface 201a of the base 201 in a front view of the heat sink 200, that is, when viewed from a direction of an arrow AR3 in FIG. 13. On the other hand, the heat dissipation fins 202 on both sides in the X direction are provided in a state of extending in the direction of a normal line AX₂₀₁ₐ of the base surface 201a extending in the Z direction in a side view, that is, when viewed from a direction of an arrow AR4 in FIG. 13. As illustrated in FIG. 14, WO 2023/246095 A1 also describes a similar heat sink 300. In FIG. 14, reference numeral 301 represents a base, reference numeral 301a represents a base surface of the base 301, and reference numeral 302 represents a heat dissipation fin provided on the base surface 301a. Furthermore, reference number AX₃₀₁ₐ represents a normal line of the base surface 301a.

On the other hand, the present inventors have studied improving heat dissipation performance of a naturally air-cooled base station device by using, as a heat dissipation fin, a heat dissipation fin having an acute inclination angle with respect to a normal line of a base surface extending in the Z direction in side view and extending upward in a gravity direction.

### SUMMARY

However, WO 2021/148140 A1 and WO 2023/246095 A1 do not describe improving heat dissipation performance of a naturally air-cooled base station device by using, as a heat dissipation fin, a heat dissipation fin having an acute inclination angle with respect to a normal line of a base surface in side view and extending upward in the gravity direction, and there is room for improvement.

A base station device of an example aspect of the present disclosure includes a device body including a heat sink, the device body being installed at a depression angle in a state where an antenna surface is facing a lower side in a gravity direction and a heat sink surface is facing an upward relative to gravity, in which the heat sink includes a base including a base surface, and at least one heat dissipation fin, and the heat dissipation fin is provided obliquely with respect to the base surface.

A method of cooling a base station device according to an example aspect of the present disclosure uses a heat sink including a base including a base surface and at least one heat dissipation fin provided obliquely with respect to the base surface.

An example object of the present disclosure is to provide a base station device and a method of cooling the base station device capable of improving heat dissipation performance of a naturally air-cooled base station device by using, as a heat dissipation fin, a heat dissipation fin having an acute inclination angle with respect to a normal line of a base surface in side view and extending upward in a gravity direction.

### BRIEF DESCRIPTION OF DRAWINGS

The above and other aspects, features and advantages of the present disclosure will become more apparent from the following description of certain exemplary embodiments when taken in conjunction with the accompanying drawings, in which:

FIG. 1 is a side view illustrating an outline of a base station device installed at an angle of depression with an antenna surface facing a lower side in a gravity direction and a heat sink surface facing an upward relative to gravity;

FIG. 2A is an example of top heat in a general heat sink, and FIG. 2B is an example of bottom heat in the general heat sink;

FIG. 3 is a perspective view of a heat sink;

FIG. 4 is an enlarged perspective view of the inside of a rectangle in FIG. 3;

FIG. 5 is a side view of the heat sink as viewed from a direction of an arrow in FIG. 3;

FIG. 6A is a side view illustrating an outline of the heat sink of the present disclosure, and FIG. 6B is a side view illustrating an outline of the heat sink of the related art in which the heat dissipation fin is obliquely provided in the base surface;

FIG. 7A is a view in which a movement path of the heated air is written in FIG. 6A, and FIG. 7B is a view illustrating a left half of a front view of a heat sink of the related art illustrating an outline of the heat dissipation fin;

FIG. 8 is a graph of a simulation result imitating the base station device;

FIG. 9 is a graph of a simulation result imitating the base station device;

FIGS. 10A, 10B, and 10C are examples in which the inclination angle of the heat dissipation fin is increased the greater the distance from the base surface, that is, the greater the Z coordinate;

FIG. 11 is an example in which a convex portion formed with a groove is provided on the base surface, and the heat dissipation fin manufactured separately from the base is joined to the groove;

FIG. 12A is an example of the heat sink including a rotating structure for rotating the heat dissipation fin, and is an example before the inclination angle is adjusted, and FIG. 12B is an example after the inclination angle is adjusted;

FIG. 13 is a perspective view of a heat sink described in WO 2021/148140A1; and

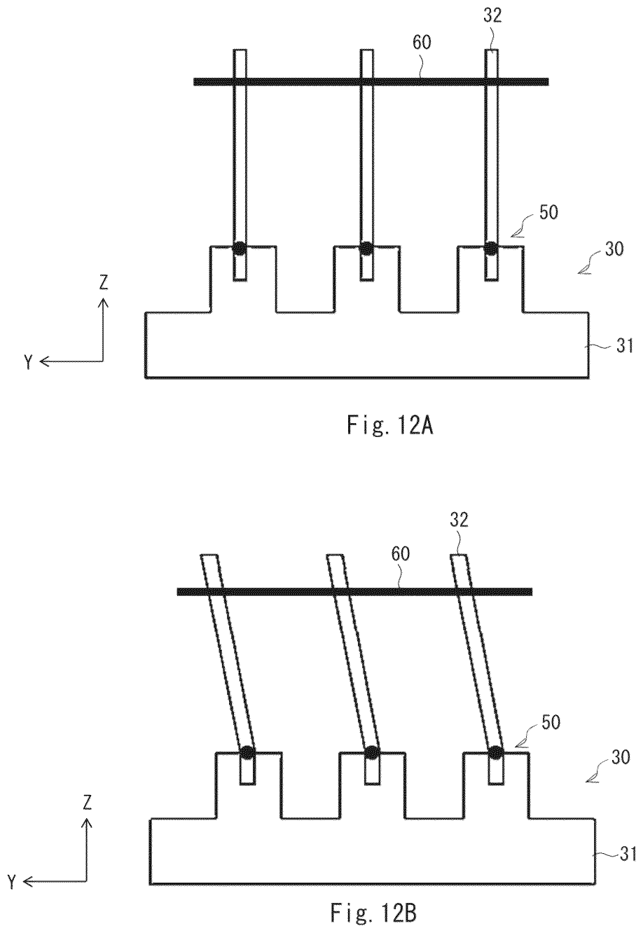

FIG. 14 is a perspective view of a heat sink described in WO 2023/246095 A1.

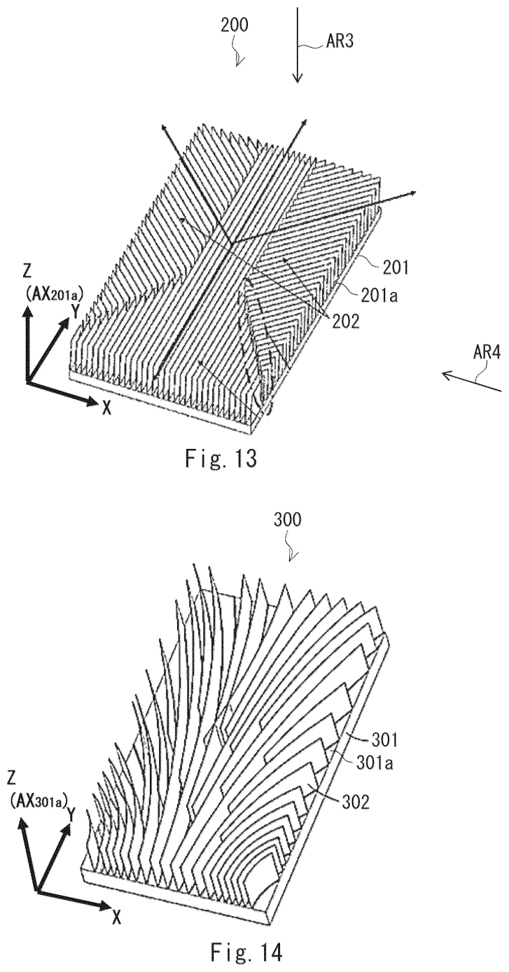

### EXAMPLE EMBODIMENT

Hereinafter, specific example embodiments to which the present disclosure is applied will be described in detail with reference to the drawings. In the drawings, the same elements are denoted by the same reference numerals, and repeated description is omitted as necessary for clarity of description. In the drawings of the present disclosure, the X-axis represents the device lateral direction. The Y-axis represents the device longitudinal direction. The Z-axis represents the device thickness direction.

First, matters studied by the present inventors will be described.

With increase in the information communication amount of mobile phones and the like due to the development of the Internet of Things (IoT), the amount of heat generated by a base station device that relays long-distance communication tends to increase. On the other hand, development in the material of the element as the heat source has not progressed, and the upper limit of the element temperature is substantially constant. Therefore, improvement of heat dissipation performance is required. The improvement of heat dissipation performance is achieved by, for example, reducing the thermal resistance of the heat sink. The element temperature is simply expressed by the following formula (1).

$$Element temperature = environmental temperature + temperature rise of heat sink portion = environmental temperature + heat generation amount \times thermal resistance of heat sink = environmental temperature + heat generation amount \times ( heat exchange {area}^{- 1} \times convective heat transfer {coefficient}^{- 1} ) \qquad ( 1 )$$

The simplest measure for improving the heat dissipation performance is to increase a heat exchange area by increasing the size of the heat sink. However, since the base station device is installed in existing facilities such as utility poles and walls, weight reduction is a customer value from the viewpoint of workability at the time of installation and the withstanding load of the installing place, and thus this measure is not desirable.

The next simple measure is to increase the convective heat transfer coefficient by forced air-cooling. However, since the base station device is installed at a high place outdoors, the cost of regular maintenance inspection and maintenance replacement of one or more fans, a dustproof filter, and the like increases, and thus this measure is also not desirable.

In view of the above, as a measure for improving the convective heat transfer coefficient, for example, as disclosed in WO 2021/148140 A1 and WO 2023/246095 A1, a method of adjusting the angle of the heat dissipation fin within a base surface (X-Y surface) of the heat sink is considered.

However, even with these measures, the heat dissipation performance is reaching its limit.

In view of the above, a base station device 1 completed by the present inventors that can improve heat dissipation performance will be described below.

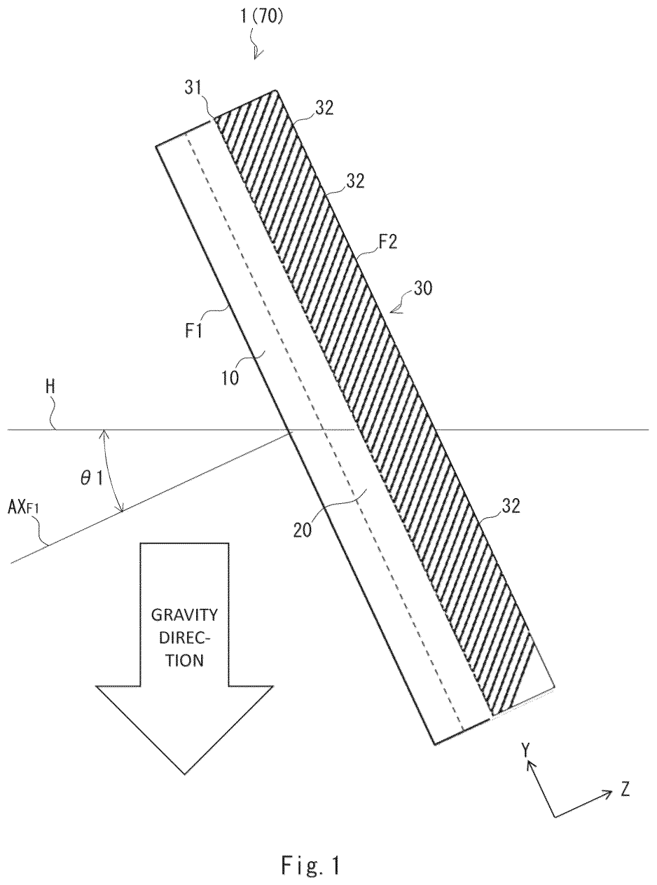

FIG. 1 is a side view illustrating an outline of a base station device 1 installed at an angle of depression with an antenna surface F1 facing the lower side in the gravity direction and a heat sink surface F2 facing the upward relative to gravity. The angle of depression is an angle formed by the horizontal plane H and a normal line AX_{F1} of the antenna surface F1, the angle facing downward with respect to the horizontal plane H. Reference numeral θ1 in FIG. 1 represents the angle of depression. Hereinafter, it is described as a depression angle θ1. In FIG. 1, depression angle θ1=25 degrees.

The base station device 1 has a horizontal width of 400 mm×a vertical width of 600 mm×a thickness of about 100 mm to 200 mm. It is assumed that the base station device 1 is used by natural air-cooling. That is, the base station device 1 does not include a means for forced air-cooling such as a cooling fan.

Basically, the base station device 1 is installed outdoors. At this time, if there is an obstacle between the base station device 1 and the communication partner, radio waves are attenuated, and the stability of communication deteriorates. In order to avoid this, it is desirable that the base station device 1 is installed with a height difference from a communication partner. Here, since the communication partner is basically a user near the ground, the base station device 1 is often installed at a higher place. As the antenna deviates from the front, the radio wave becomes weaker, and the stability of communication deteriorates. Therefore, in a case where the base station device 1 is installed at a high place, it is desirable to install the base station device 1 at a depression angle in a state where the antenna surface F1 of the base station device 1 is facing a communication partner on a lower side with respect to the base station device 1, that is, the lower side in the gravity direction, and the heat sink surface F2 is facing the upward relative to gravity.

According to the present disclosure, a heat dissipation fin 32 of a heat sink 30 constituting the base station device 1 is provided in a state where a distal end portion thereof is inclined to the upward relative to gravity. Therefore, in a case where the base station device 1 is installed at a depression angle as illustrated in FIG. 1, the heat sink 30 can be brought into a state close to bottom heat having higher heat dissipation performance than top heat.

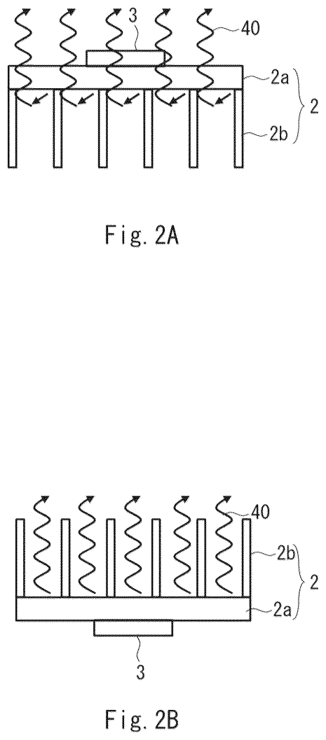

FIG. 2A is an example of top heat in a general heat sink, and FIG. 2B is an example of bottom heat in a general heat sink.

As illustrated in FIG. 2A, in the top heat, a base 2a of the heat sink 2 with a heat source 3 is disposed above the heat dissipation fin 2b of the heat sink 2. On the other hand, as illustrated in FIG. 2B, in the bottom heat, the base 2a of the heat sink 2 with the heat source 3 is disposed below the heat dissipation fin 2b of the heat sink 2.

In the case of the top heat illustrated in FIG. 2A, heated air 40 after heat exchange is shielded by the base 2a and the heat dissipation fin 2b, and thus is less likely to be released from the heat sink 2. On the other hand, in the case of the bottom heat illustrated in FIG. 2B, the heated air 40 after heat exchange can be smoothly released from the heat sink 2 without being shielded by the base 2a and the heat dissipation fin 2b. Therefore, in general, the heat dissipation performance is improved in a case where the heat sink is used in the bottom heat state rather than in the top heat state.

According to the present disclosure, since the heat dissipation fin 32 is provided in a state where its distal end portion is inclined by a predetermined angle toward an upward relative to gravity, the heat sink 30 can be brought into a state close to bottom heat at a smaller depression angle θ1. As a result, heat dissipation performance can be improved.

Next, a configuration example of the base station device 1 will be described.

As illustrated in FIG. 1, the base station device 1 includes an antenna unit 10, a substrate unit 20, and a heat sink 30. The antenna unit 10, the substrate unit 20, and the heat sink 30 constitute a device body 70. The device body 70 is installed at a depression angle as illustrated in FIG. 1.

Although not illustrated, the antenna unit 10 includes, for example, an antenna and a radome that is a cover for protecting the antenna. As the antenna, for example, a plurality of patch antennas may be used.

Although not illustrated, the substrate unit 20 includes an element such as a Field Programmable Gate Array (FPGA) for signal processing, a Band-pass filter (BPF) for noise processing, a power supply for supplying power to the antenna, the element, or the like, a substrate on which a connector or the like for connecting to an external device is mounted, and a housing for protecting these.

Next, the heat sink 30 will be described.

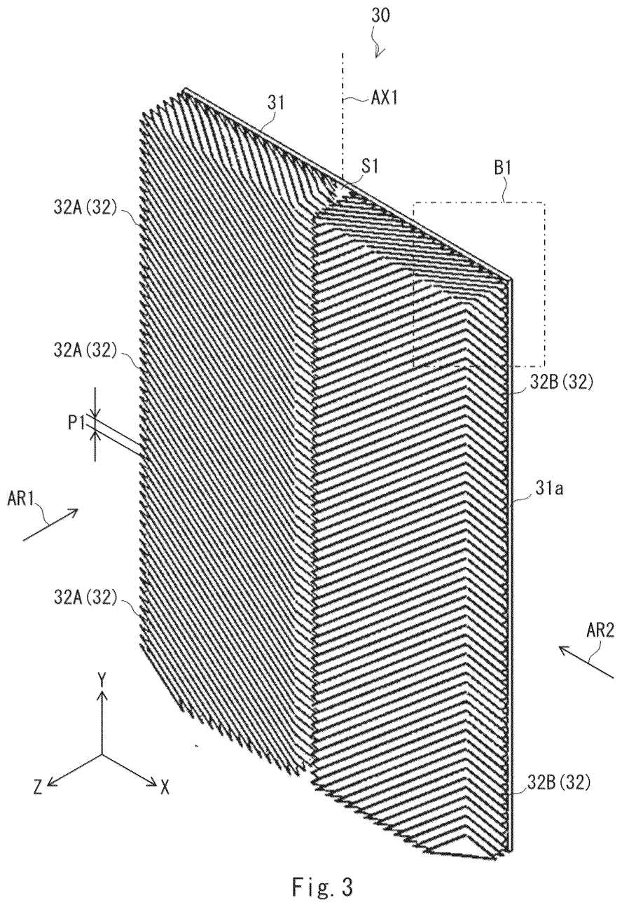

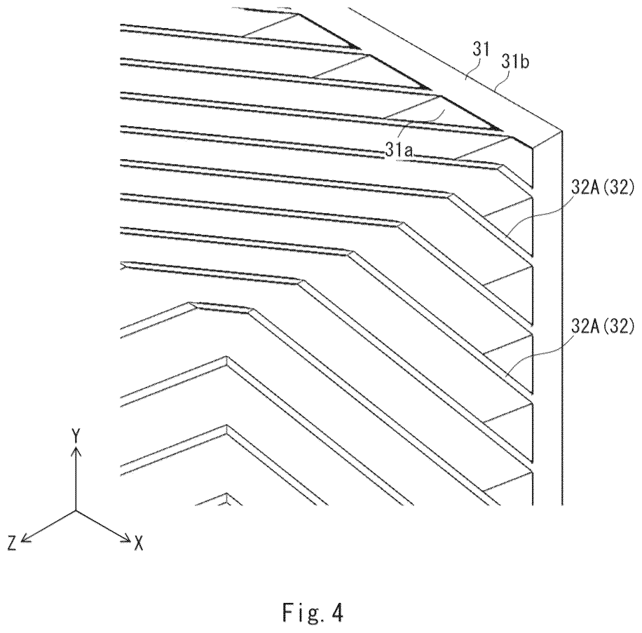

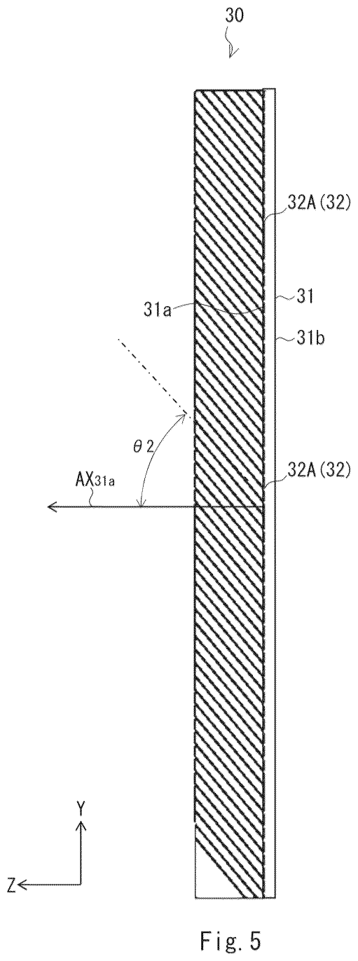

FIG. 3 is a perspective view of the heat sink 30, FIG. 4 is an enlarged perspective view of the inside of a rectangle B1 in FIG. 3, and FIG. 5 is a side view of the heat sink 30 as viewed from a direction of an arrow AR2 in FIG. 3. As illustrated in FIGS. 3 to 5, the heat sink 30 includes a base 31 that comes into contact with a heat source to receive heat, and a plurality of heat dissipation fins 32. The heat source is a portion that generates heat in a case where the base station device 1 operates, and is, for example, an element (not illustrated) mounted on the substrate unit 20. At least one heat dissipation fin 32 may be provided.

The base 31 is a portion of the heat sink 30 that comes into contact with the heat source to receive heat. As illustrated in FIG. 5, the base 31 is a flat plate-shaped base having a thickness in the Z direction including one main surface 31a including the plurality of heat dissipation fins 32 and the other main surface 31b that is on the opposite side and that comes into contact with the heat source to receive heat. Hereinafter, one main surface 31a including the plurality of heat dissipation fins 32 will be described as a base surface 31a. The base surface 31a is an X-Y plane, and the other main surface 31b is a plane parallel to the X-Y plane. The heat dissipation fin 32 is a portion that dissipates heat received from the base 31 to outside air. Although not illustrated, the substrate unit 20 is attached to the heat sink 30 with a screw or the like in a state where the other main surface 31b of the heat sink 30 and the substrate unit 20 that is the heat source are connected. At this time, the element that is the heat source is in contact with the other main surface 31b of the heat sink 30 via a thermal conduction member (TIM: Thermal Interface Material) and a thermal diffusion member such as a vapor chamber. Although not illustrated, the base 31 and the housing constituting the substrate unit 20 may be integrated with each other or may be separate bodies from each other.

As illustrated in FIG. 3, the heat dissipation fin 32 includes a group of heat dissipation fins 32A arranged on the left side with respect to a center line AX1 extending in the Y direction and a group of heat dissipation fins 32B arranged on the right side with respect to the center line AX1. The group of heat dissipation fins 32A and the group of heat dissipation fins 32B are arranged symmetrically with respect to the center line AX1, and have similar configuration. Therefore, hereinafter, the group of heat dissipation fins 32A will be representatively described, and the description of the group of heat dissipation fins 32B will be omitted. Hereinafter, in a case where the heat dissipation fin 32A and the heat dissipation fin 32B do not need to be distinguished from each other, they are referred to as heat dissipation fins 32.

The group of heat dissipation fins 32A includes a plurality of plate-shaped bodies having a flat plate shape with the left end portion inclined toward the upward relative to gravity. The group of heat dissipation fins 32A is provided on the base surface 31a of the base 31 in a state of being parallel to each other and being spaced apart from each other in the Y direction by an interval P1.

The group of heat dissipation fins 32A and the group of heat dissipation fins 32B are arranged in the X direction with a space S1 extending in the Y direction therebetween.

The group of heat dissipation fins 32A and the group of heat dissipation fins 32B form a substantially V-shape opened upward in the base surface 31a when viewed from the front side of the heat sink 30, that is, when viewed from the direction of the arrow AR1 in FIG. 3. The group of heat dissipation fins 32A and the group of heat dissipation fins 32B are not limited to be substantially V-shaped in front view of the heat sink 30, and may be substantially inverted V-shape in which the group of heat dissipation fins 32A and the group of heat dissipation fins 32B are reversed. In addition, the number of groups of the heat dissipation fins 32A and the number of groups of the heat dissipation fins 32B may be increased or may not be the same, for example, as with a substantially N-shape or a substantially W-shape.

On the other hand, the heat dissipation fin 32 is provided obliquely with respect to the base surface 31a in a side view of the heat sink 30, that is, when viewed from the direction of the arrow AR2 in FIG. 3. Hereinafter, this point will be described in comparison with the heat sink 100 of the related art in which the heat dissipation fin 102 is obliquely provided in the base surface 101a.

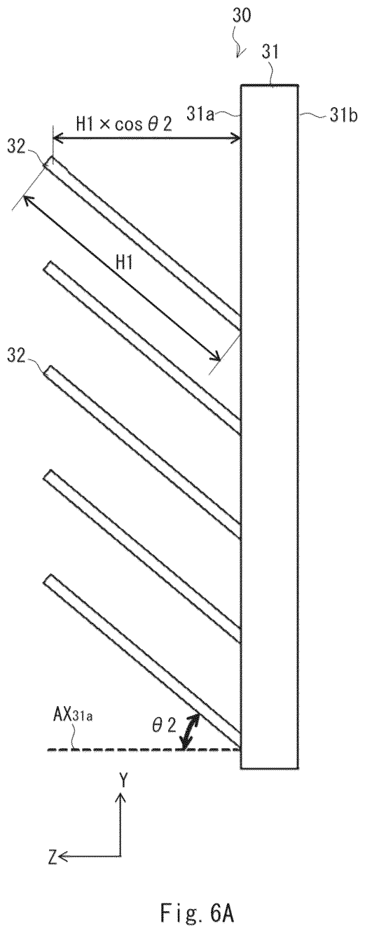

FIG. 6A is a side view illustrating an outline of the heat sink 30 of the present disclosure, and FIG. 6B is a side view illustrating an outline of the heat sink 100 of the related art in which the heat dissipation fin 102 is obliquely provided in the base surface 101a. FIG. 6A is a side view seen from a direction of an arrow AR2 in FIG. 3. FIG. 6B is also a side view seen from a direction (not illustrated) similar to the arrow AR2 in FIG. 3.

As illustrated in FIG. 6A, the heat dissipation fin 32 of the present disclosure is provided obliquely with respect to the base surface 31a in side view. Specifically, the heat dissipation fin 32 is provided in a state where its distal end portion is inclined by a predetermined angle to the upward relative to gravity in side view. More specifically, the heat dissipation fin 32 is provided on the base surface 31a in a state of having an acute inclination angle θ2 with respect to a normal line AX₃₁ₐ of the base surface 31a extending in the Z direction in side view and extending upward in the gravity direction. The inclination angle θ2 is an example of a predetermined angle of the present disclosure. The inclination angle θ2 is an acute angle, that is, an angle larger than 0 degrees and smaller than 90 degrees. The inclination angle θ2 may be represented by a positive number in order to represent the angle on the upward relative to gravity. On the other hand, as illustrated in FIG. 6B, the heat dissipation fin 102 of the related art is provided at a right angle with respect to the base surface 101a in side view. Specifically, the heat dissipation fin 102 of the related art extends in a direction in which an inclination angle with respect to the normal line AX₁₀₁ₐ of the base surface 101a extending in the Z direction in side view, that is, an angle corresponding to the inclination angle θ2 is 0 degrees.

The heat sink 30 having the above configuration may be manufactured as an integral body by, for example, casting a metal material such as aluminum or copper-based metal material, or by machining the aluminum or copper-based metal material.

Not limited to the casting or cutting described above, first, a heat dissipation fin similar to that of the related art, that is, a heat dissipation fin similar to the heat dissipation fin 102 provided at a right angle with respect to the base surface 101a in a side view as illustrated in FIG. 6B is manufactured, and then the heat dissipation fin is subjected to bending to configure the heat dissipation fin 32.

Next, an operation example of the base station device 1 having the above configuration will be described.

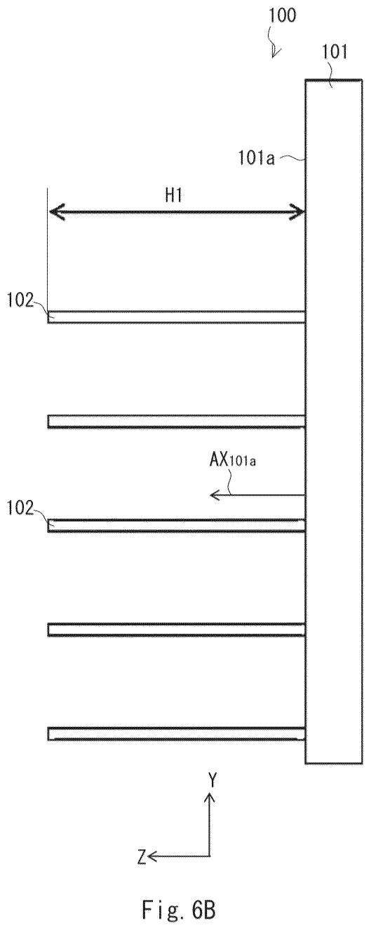

FIG. 7A is a diagram in which a movement path of the heated air 40 is written in FIG. 6A. FIG. 7B is a diagram illustrating a left half of a front view of the heat sink 100 of the related art illustrating an outline of the heat dissipation fin 102. In FIG. 7B, only the left half of the heat sink 100 of the related art is illustrated for the sake of convenience of explanation.

If the base station device 1 operates, the elements of the substrate unit 20 mainly generate heat. Heat generated by the element is transferred to the base 31 of the heat sink 30 and the heat dissipation fins 32 in this order via a thermal conduction member (TIM) and a thermal diffusion member such as a vapor chamber, and is heat exchanged with outside air having a lower temperature to be dissipated to the outside of the base station device 1. At this time, since the density of the outside air after the heat exchange, that is, the heated air 40 decreases as the temperature rises, in the case of natural air-cooling, as illustrated in FIG. 7A, the outside air moves to the upward relative to gravity, mainly in the direction of the height H1 of the heat dissipation fin 32 due to buoyancy, and is released from the heat sink 30 upon reaching the upper end of the fin.

Next, effects of the base station device 1 having the above configuration will be described.

In the related art, as illustrated in FIG. 6B, since the heat dissipation fin 102 of the related art is provided at a right angle with respect to the base surface 101a in a side view, the heated air 40, as illustrated in FIG. 7B, moves mainly in the length L1 direction of the heat dissipation fin 102 and is released from the heat sink 100 at a time point the end portion 102a in a device side surface direction is reached.

Here, in the case of a general base station device using a heat dissipation fin having a substantially V-shape, the height H1 of the heat dissipation fin is about 50 to 120 mm, and the length L1 of the heat dissipation fin is about 280 mm. That is, the length L1 of the heat dissipation fin>the height H1 of the heat dissipation fin, and the heat sink 30 having the above configuration has a shorter flow path length than the heat sink 100 of the above related art, so that the flow path resistance is small. As a result, in heat sink 30 having the above configuration, the volumetric flow rate increases and the convective heat transfer coefficient increases, so that the heat dissipation performance improves. Therefore, the heat sink 30 and thus the base station device 1 can be made smaller and lighter.

In the above related art, the height of the heat dissipation fin 102 in the Z direction=H1 as illustrated in FIG. 6B, whereas according to the base station device 1 having the above configuration, the height of the heat dissipation fin 32 in the Z direction=H1×cosθ2 as illustrated in FIG. 6A. That is, according to the base station device 1 having the above configuration, the height of the heat dissipation fin 32 in the Z direction can be reduced as compared with the above related art. As a result, the base station device 1 that is thinner in the Z direction than the above-described related art can be achieved.

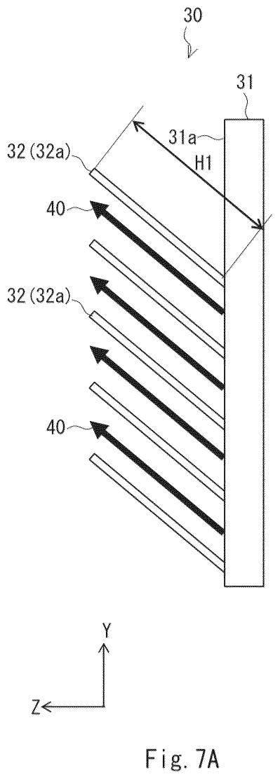

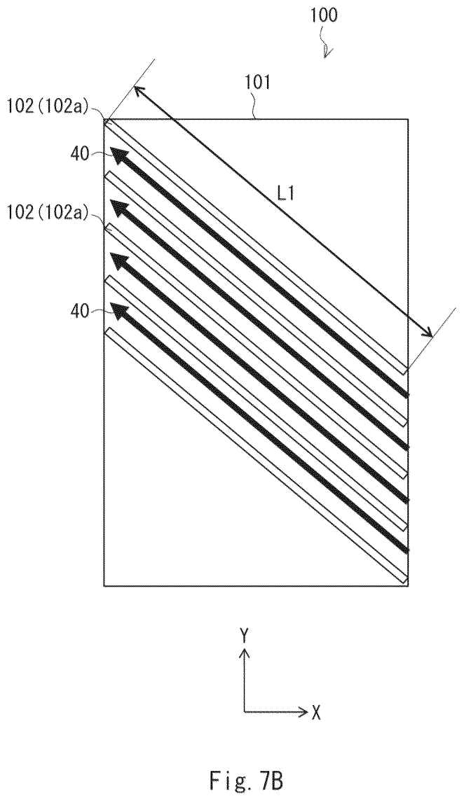

FIGS. 8 and 9 are graphs of simulation results imitating the base station device 1. In the simulation, three-dimensional simulation was performed using Simcenter Flotherm XT on a heat sink having a horizontal width of 400 mm×a vertical width of 600 mm×a height of 50 mm in the Z direction of a heat dissipation fin having a substantially V-shape. Referring to FIG. 8, in the case of depression angle θ1=50 degrees, the heat dissipation performance is higher in the case of 0 degrees<inclination angle θ2<10 degrees (present disclosure) than in the case of inclination angle θ2=0 degrees (conventional), and is maximized at inclination angle θ2=5 degrees. On the other hand, with reference to FIG. 9, comparing the inclination angle θ2=0 degrees (conventional) and the inclination angle θ2=5 degrees (present disclosure), the heat dissipation performance is substantially the same at 0 degrees≤depression angle θ1≤25 degrees, and the heat dissipation performance is higher in the inclination angle θ2=5 degrees (present disclosure) at 25 degrees<depression angle θ1≤50 degrees. The inclination angle θ2=5 degrees is not the sole case. That is, since the inclination angle θ2=5 degrees is a condition for maximizing the heat dissipation performance, the inclination angle θ2 may be equal to or greater than 5 degrees or smaller than 5 degrees if there is a margin in the heat dissipation performance. In other words, as the inclination angle θ2, an angle more appropriate for the balance between the required heat dissipation performance and the device size may be adopted. In addition, the heat dissipation performance is maximized at the inclination angle θ2=5 degrees in the case of the present simulation condition, and changes depending on conditions such as the dimension of the heat sink.

As described above, according to the present example embodiment, the heat dissipation performance of the naturally air-cooled base station device 1 can be improved by using, as the heat dissipation fin, the heat dissipation fin 32 having an acute inclination angle θ2 with respect to the normal line AX₃₁ₐ of the base surface 31a in side view and extending upward in the gravity direction.

Hereinafter, modified examples will be described.

### First Modified Example

In the above-described example embodiment, the example has been described in which the flat plate-shaped body is used as the heat dissipation fin 32, and the inclination angle θ2 with respect to the normal line AX₃₁ₐ of the base surface 31a is uniform (constant) regardless of the distance from the base surface 31a, but this is not the sole case.

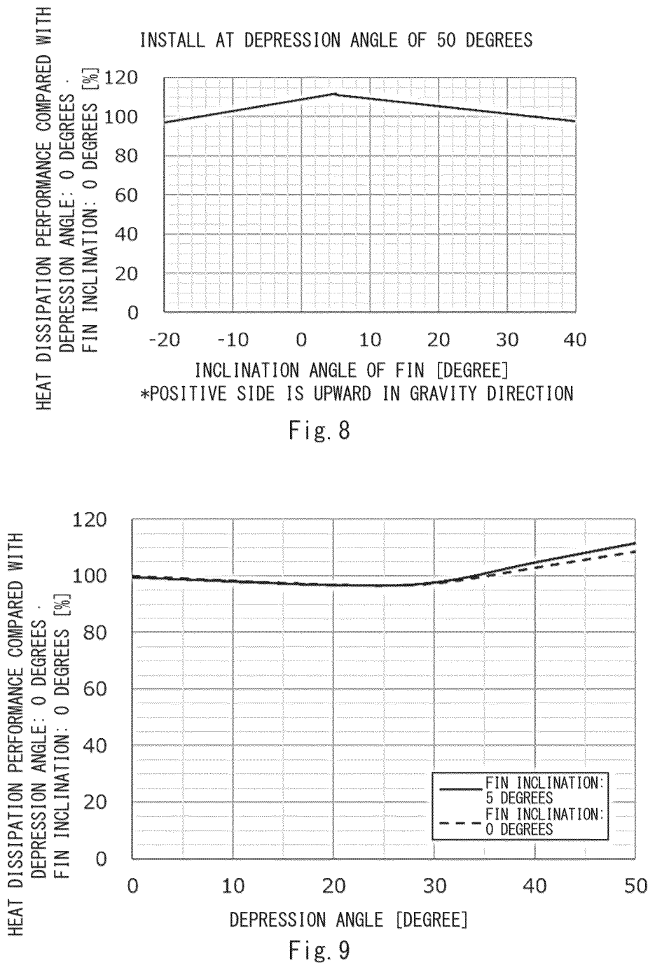

For example, as illustrated in FIGS. 10A, 10B, and 10C, the inclination angle θ2 of the heat dissipation fin 32 may be different according to the distance from the base surface 31a. That is, the inclination angle θ2 of the heat dissipation fin 32 may be non-uniform. FIGS. 10A, 10B, and 10C illustrate an example in which the inclination angle θ2 of the heat dissipation fin 32 is increased the greater the distance from the base surface 31a, that is, the greater the Z coordinate.

According to the first modified example, the flow of the heated air in the height direction of the heat dissipation fin 32 gradually changes to upward in the gravity direction.

If the heat dissipation fin 32 is bent at the root thereof, the acute angle portion of the corner becomes a stagnation region, and thus the flow path resistance becomes smaller if the heat dissipation fin is bent at a location slightly away from the root thereof. In addition, the total flow path resistance becomes smaller if the heat dissipation fin 32 is bent in multiple stages instead of being bent to a target angle at one time. Therefore, as described above, the airflow rate increases by non-uniformly changing the inclination angle θ2 of the heat dissipation fin 32 according to the Z coordinate, and the convective heat transfer coefficient increases, so that the heat dissipation performance improves.

### Second Modified Example

In <First Modified Example>, the example has been described in which the inclination angle θ2 of the heat dissipation fin 32 is non-uniformly changed according to the Z coordinate, but the inclination angle θ2 of the heat dissipation fin 32 may be non-uniformly changed further according to the X coordinate and the Y coordinate.

In general, the closer to the center of the device, the larger the number of elements attached to the heat sink and the greater the heat generation amount, that is, the higher the heat generation density tends to be, and the required heat dissipation performance also becomes higher. Therefore, the inclination angle θ2 of the heat dissipation fin 32 may be non-uniformly changed according to the Z coordinate as in <First Modified Example> only at such a site. Conversely, the heat generation density tends to be lower the closer to the corner of the device, and the required heat dissipation performance also becomes lower. Therefore, the number of times of bending of the heat dissipation fin 32 may be reduced or the bending may not be performed only at such a site as compared with a site having a high heat generation density.

According to the present second modified example, it is possible to provide the heat sink 30 having heat dissipation performance corresponding to the condition of the heat generation density.

### Third Modified Example

In the above-described example embodiment, the example has been described in which the base 31 and the heat dissipation fin 32 are manufactured as an integral body, but this is not the sole case. For example, the heat sink 30 may be manufactured by combining the base 31 and the heat dissipation fin 32 manufactured separately.

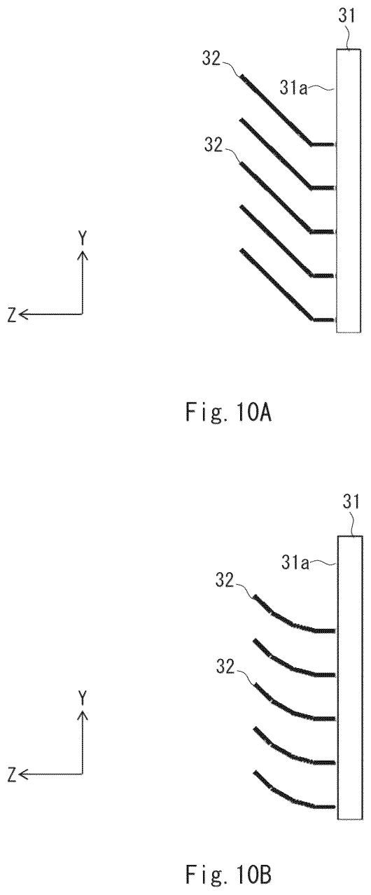

FIG. 11 illustrates an example in which a convex portion formed with a groove is provided on the base surface 31a, and a lower end portion of the heat dissipation fin 32 manufactured separately from the base 31 is joined to the groove. The joining method may be, for example, welding, mechanical fastening, or adhering. The materials of the base 31 and the heat dissipation fin 32 may be the same with each other or different from each other.

Before the base 31 and the heat dissipation fin 32 are joined, the heat dissipation fin 32 is bent in advance. As the heat dissipation fin 32, a heat dissipation fin obtained by manufacturing a flat heat dissipation fin and performing bending on the flat heat dissipation fin to bend the heat dissipation fin may be used, or a heat dissipation fin manufactured in a bent state from the beginning may be used.

According to the present third modified example, the heat sink 30 can be easily manufactured. In particular, as illustrated in FIG. 3, the effect is greater in a case where the heat dissipation fin 32 is inclined in both the front view and the side view, that is, in both the X-Y plane and the Y-Z plane, or in a case where the inclination angle of the heat dissipation fin 32 is made non-uniform as in the first modified example and the second modified example.

Furthermore, a site whose shape is generally complicated and the degree of difficulty in manufacturing is high is often cast, and a material having a low thermal conductivity tends to be used. However, according to the third modified example, different materials can be used according to the degree of difficulty in manufacturing of the base 31 and the heat dissipation fin 32. Therefore, the heat dissipation performance improves by partially using a material having a high thermal conductivity.

### Fourth Modified Example

In the above-described example embodiment, the example has been described in which the inclination angle θ2 of the heat dissipation fin 32 is fixed, but this is not the sole case. For example, the heat sink 30 may include a rotating structure (an example of the inclination angle adjustment mechanism of the present disclosure) for rotating the heat dissipation fin 32 in order to adjust the inclination angle θ2.

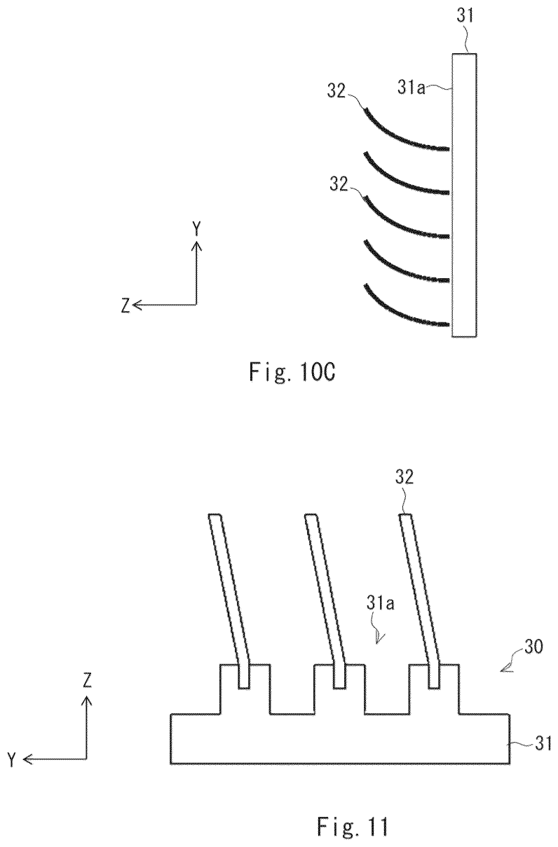

FIG. 12A is an example of the heat sink 30 including a rotating structure 50 for rotating the heat dissipation fin 32, and is an example before the inclination angle θ2 is adjusted, and FIG. 12B is an example after the inclination angle θ2 is adjusted. The rotating structure 50 is, for example, a hinge, and is provided, for example, at a root of the heat dissipation fin 32. In order to maintain the heat dissipation fins 32 parallel to each other, a spacer 60 for fixing the interval between the heat dissipation fins 32 may be provided. Although not illustrated, the heat dissipation fin 32 may be manually rotated, or may be electrically rotated using a power source such as a motor and a mechanism that transmits rotation of the motor. The rotating structure 50 may be provided other than at the root of the heat dissipation fin 32. Furthermore, a plurality of rotating structures 50 may be provided.

According to the fourth modified example, the inclination angle θ2 of the heat dissipation fin 32 can be changed after the base station device 1 is manufactured by the action of the rotating structure 50. Therefore, the heat dissipation performance improves by optimally adjusting the inclination angle θ2 of the heat dissipation fin 32 in accordance with the installation state of the base station device 1 such as the depression angle θ1 or the installation environment of the base station device 1 such as natural wind.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment and each modified example can be appropriately combined with other example embodiments and modified examples.

Each drawing is merely illustrative for describing one or more example embodiments. Each of the drawings is not associated with only one specific example embodiment, but may be associated with one or more other example embodiments. As those of ordinary skill in the art will appreciate, various features or steps described with reference to any one of the figures may be combined with features or steps shown in one or more other figures, for example, to create example embodiments that are not explicitly illustrated or described. All of the features or steps shown in any one of the figures for describing the exemplary example embodiments are not necessarily mandatory, and some features or steps may be omitted. The order of the steps described in any drawing may be changed as appropriate.

Some or all of the above example embodiments may also be described as the following Supplementary Notes, but are not limited to the following Supplementary Notes.

### Supplementary Note 1

A base station device including,
a device body including a heat sink, the device body being installed at a depression angle in a state where an antenna surface is facing a lower side in a gravity direction and a heat sink surface is facing an upward relative to gravity, in which
the heat sink includes,
a base including a base surface, and
at least one heat dissipation fin, and
the heat dissipation fin is provided obliquely with respect to the base surface.

### Supplementary Note 2

The base station device according to supplementary note 1, in which the heat dissipation fin is provided in a state where a distal end portion thereof is inclined by a predetermined angle toward the upward relative to gravity.

### Supplementary Note 3

The base station device according to supplementary note 1, in which an angle formed by a normal line of the base surface and the heat dissipation fin varies depending on a distance from the base surface.

### Supplementary Note 4

The base station device according to supplementary note 1, in which an angle formed by a normal line of the base surface and the heat dissipation fin varies depending on a heat generation density of an element attached to the base.

### Supplementary Note 5

The base station device according to supplementary note 1, in which the heat dissipation fin has a substantially V-shape, a substantially inverted V-shape, a substantially W-shape, a substantially inverted W-shape, or a substantially N-shape in a front view of the heat sink.

### Supplementary Note 6

The base station device according to supplementary note 1, in which the heat dissipation fin is joined to the base formed separately from the heat dissipation fin.

### Supplementary Note 7

The base station device according to supplementary note 6, in which the joining is welding, mechanical fastening, or adhesion.

### Supplementary Note 8

The base station device according to supplementary note 2, further including at least one inclination angle adjustment mechanism for adjusting the predetermined angle.

### Supplementary Note 9

A method of cooling a base station device using a heat sink including a base including a base surface and at least one heat dissipation fin provided obliquely with respect to the base surface.

### Supplementary Note 10

The method of cooling the base station device according to supplementary note 9, in which the heat dissipation fin is provided in a state where a distal end portion thereof is inclined by a predetermined angle toward an upper side in a gravity direction.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each embodiment can be appropriately combined with at least one of embodiments.

Each of the drawings or figures is merely an example to illustrate one or more example embodiments. Each figure may not be associated with only one particular example embodiment, but may be associated with one or more other example embodiments. As those of ordinary skill in the art will understand, various features or steps described with reference to any one of the figures can be combined with features or steps illustrated in one or more other figures, for example to produce example embodiments that are not explicitly illustrated or described. Not all of the features or steps illustrated in any one of the figures to describe an example embodiment are necessarily essential, and some features or steps may be omitted. The order of the steps described in any of the figures may be changed as appropriate.

What is claimed is:

1. A base station device comprising:
a device body including a heat sink, the device body being installed at a depression angle in a state where an antenna surface is facing a lower side in a gravity direction and a heat sink surface is facing an upward relative to gravity, wherein
the heat sink includes,
a base including a base surface, and
at least one heat dissipation fin, and
the heat dissipation fin is provided obliquely with respect to the base surface.

2. The base station device according to claim 1, wherein the heat dissipation fin is provided in a state where a distal end portion thereof is inclined by a predetermined angle toward the upward relative to gravity.

3. The base station device according to claim 1, wherein an angle formed by a normal line of the base surface and the heat dissipation fin varies depending on a distance from the base surface.

4. The base station device according to claim 1, wherein an angle formed by a normal line of the base surface and the heat dissipation fin varies depending on a heat generation density of an element attached to the base.

5. The base station device according to claim 1, wherein the heat dissipation fin has a substantially V-shape, a substantially inverted V-shape, a substantially W-shape, or a substantially inverted W-shape in a front view of the heat sink.

6. The base station device according to claim 1, wherein the heat dissipation fin is joined to the base formed separately from the heat dissipation fin.

7. The base station device according to claim 6, wherein the joining is welding, mechanical fastening, or adhesion.

8. The base station device according to claim 2, further comprising at least one inclination angle adjustment mechanism for adjusting the predetermined angle.

9. A method of cooling a base station device using a heat sink including a base including a base surface and at least one heat dissipation fin provided obliquely with respect to the base surface.

10. The method of cooling the base station device according to claim 9, wherein the heat dissipation fin is provided in a state where a distal end portion thereof is inclined by a predetermined angle toward an upper side in a gravity direction.
